(19) United States
(12) Patent Application Publication
(10) Pub. No.: US 2012/0213005 A1
(43) Pub. Date: Aug. 23, 2012

(54) NON-VOLATILE MEMORY DEVICE, MEMORY CONTROLLER, AND METHODS THEREOF

(75) Inventor: Sang Hoon Lee, Hwaseong-si (KR)

(73) Assignee: SAMSUNG ELECTRONICS CO., LTD., Suwon-si (KR)

(21) Appl. No.: 13/398,204

(22) Filed: Feb. 16, 2012

Related U.S. Application Data
(60) Provisional application No. 61/445,281, filed on Feb. 22, 2011.

(30) Foreign Application Priority Data
Feb. 22, 2011 (KR) 10-2011-0015475

(51) Int. Cl. G11C 16/10

(52) U.S. Cl. 365/185.11

(57) ABSTRACT

The method includes receiving a block address and an erase command output from a controller, and changing, until an erase operation performed according to the erase command on a block corresponding to the block address is completed, a parameter value related to the erase operation. The method further includes storing information corresponding to a finally changed parameter value, and transmitting the information to the controller according to a command output from the controller.

### CROSS-REFERENCE TO RELATED APPLICATIONS

This application claims the priority benefit of U.S. provisional patent application No. 61/445,281 filed on Feb. 22, 2011 and Korean patent application No. 10-2011-0015475 filed on Feb. 22, 2011, the disclosure of each of which is hereby incorporated herein by reference in its entirety.

### BACKGROUND

Embodiments of the present inventive concepts relate to a semiconductor device, and more particularly, to a method for detecting deterioration of a flash memory cell and a device performing the method.

A life time of a flash memory device is determined according to the number of program cycles and/or erase cycles. Accordingly, so as to use the flash memory device stably, a wear-leveling scheme on a plurality of blocks included in the flash memory device is applied. The wear-leveling scheme is applied according to the number of erase cycles on each of the plurality of blocks.

### SUMMARY

The present general inventive concepts provide a method for detecting deterioration of a flash memory and a device associated therewith. At least some embodiments provide for detection in real time. At least some embodiments provide a method adjusting a level of wear-leveling of a block, which is an object of an erase operation by using deterioration information.

An embodiment is directed to an operation method of a non-volatile memory device, including receiving a block address and an erase command output from a controller, changing, until an erase operation on a block corresponding to the block address performed according to the erase command is completed, a parameter value related to the erase operation, storing information corresponding to a finally changed parameter value, and transmitting the information to the controller according to a command output from the controller. The command may be a read status command requiring information on success or failure of the erase operation.

The parameter value is at least one of time needed until the block is erased, an incremental-step-pulse erase (ISPE) loop count, an incremental-step-pulse erase (ISPE) voltage, at least one of width and amplitude of each erase pulse of each erase loop of the ISPE, at least one of width and amplitude of an erase verify pulse, temperature of the non-volatile memory device, a voltage supplied to the block during the erase operation, and an erase count on the block.

The information may be transmitted with a state bit indicating success or failure of the erase operation to the controller.

An example embodiment is directed to an operation method of a controller, including transmitting, to erase a block in a non-volatile memory device, a block address on the block and an erase command to the non-volatile memory device, transmitting a command to the non-volatile memory device, receiving information which is output from the non-volatile memory device in response to the command and corresponds to a parameter value related to an erase operation according to the erase command, analyzing the received information; and sorting a level of wear-leveling of the block into one of a plurality of groups according to the analyzing. The command may be a read status command requiring information on success or failure of the erase operation.

The operation method of the controller may further include re-sorting a level of current wear-leveling of the block, according to the analysis result. The operation method of the controller may further include transmitting, by the controller, a result of the sorting or the re-sorting to the non-volatile memory device.

The information indicates at least one of time needed until the block is erased, an incremental-step-pulse erase (ISPE) loop count, an incremental-step-pulse erase (ISPE) voltage, at least one of width and amplitude of each erase pulse of each erase loop of the ISPE, at least one of width and amplitude of an erase verify pulse, temperature of the non-volatile memory device, a voltage supplied to the block during the erase operation, and an erase count on the block.

An example embodiment is directed to an operation method of a memory system including a non-volatile memory device where a block is embodied and a controller controlling an operation of the non-volatile memory device, including transmitting, by the controller, a block address on the block and an erase command to the non-volatile memory device, transmitting, by the controller, a command to the non-volatile memory device, receiving, by the controller; information, which is output from the non-volatile memory device in response to the command and corresponds to a parameter value related to an erase operation according to the erase command; analyzing, by the controller, the information; and sorting a level of wear-leveling of the block into one of a plurality of groups according to the analyzing.

The operation method of the memory system may further include changing, by the non-volatile memory device, the parameter value related to the erase operation until the erase operation on the block performed according to the erase command is completed; storing a finally changed parameter value as the information; and transmitting, by the non-volatile memory device, the information to the controller in response to the read status command when the command is a read status command.

The operation method of the memory system may further include re-sorting, by the controller, a level of current wear-leveling of the block, the re-sorting resulting in at least one block changing from one group to another.

The memory system may be a smart card or a Solid State Drive (SSD).

An example embodiment is directed to a memory controller, including a memory configured to store a program, and a processor configured to perform the program stored in the memory. As the program is performed, the processor is configured to perform, in order to erase a block embodied in a non-volatile memory device, transmit a block address on the block and an erase command to the non-volatile memory device, transmit a command to the non-volatile memory device, receive information, which is output from the non-volatile memory device and corresponds to a parameter value related to an erase operation according to the command, analyze the information; and sorting a level of wear-leveling of the block into one of a plurality of groups according to an analysis result.

The command may be a read status command requiring information on success or failure of the erase operation. The information indicates at least one of time needed until the block is erased, an incremental-step-pulse erase (ISPE) loop count, an incremental-step-pulse erase (ISPE) voltage, at least one of width and amplitude of each erase pulse of each erase loop of the ISPE, at least one of width and amplitude of an erase verify pulse, temperature of the non-volatile memory device, a voltage supplied to the block during the erase operation, and an erase count on the block.

An example embodiment is directed to a non-volatile memory device, including a memory cell array, which includes a plurality of blocks, and a control logic configured to receive a block address and an erase command output from a controller; change, until an erase operation performed according to the erase command is completed on a block designated among the plurality of blocks according to the block address, a parameter value related to the erase operation; store information corresponding to a finally changed parameter value into a memory; and transmit the information to the controller according to a command output from the controller.

The command may be a read status command requiring information on success or failure of the erase operation. The information is at least one of time needed until the block is erased, an incremental-step-pulse erase (ISPE) loop count, an incremental-step-pulse erase (ISPE) voltage, at least one of width and amplitude of each erase pulse of each erase loop of the ISPE, at least one of width and amplitude of an erase verify pulse, temperature of the non-volatile memory device, a voltage supplied to the block during the erase operation, and an erase count on the block.

The information may be transmitted with a status bit displaying success or failure of the erase operation to the controller.

A method of wear-leveling includes receiving deterioration information for a block in a non-volatile memory, determining a deterioration indicator based on the deterioration information, the deterioration indicator representing an amount of charge trapped in memory cells of the block, and sorting the block into a wear-leveling group based on the deterioration indicator.

### BRIEF DESCRIPTION OF THE DRAWINGS

These and/or other aspects and/or advantages of the inventive concepts will become apparent and more readily appreciated from the following description of the embodiments, taken in conjunction with the accompanying drawings of which:

FIG. 1 shows a block diagram of a memory system including a non-volatile memory device according to an example embodiment;

FIG. 2 shows an example embodiment of status register data output from the non-volatile memory device illustrated in FIG. 1;

FIG. 3 shows an example embodiment of an operational timing diagram of the memory system illustrated in FIG. 1;

FIG. 4 shows a schematic block diagram of the non-volatile memory device illustrated in FIG. 1;

FIG. 5 shows a block diagram of the non-volatile memory device illustrated in FIG. 1;

FIG. 6 is a flowchart for explaining an erase operation of the non-volatile memory device illustrated in FIG. 1 and an output process of state register data;

FIG. 7 is a timing diagram for explaining an incremental-step-pulse erase (ISPE) scheme performed in the non-volatile memory device illustrated in FIG. 1;

FIG. 8 shows an wearing index and program/erase cycles

FIG. 9 is a flowchart for explaining a program operation of the non-volatile memory device illustrated in FIG. 1 and an output process of status register data;

FIG. 10 shows another example embodiment of an operational timing diagram of the memory system illustrated in FIG. 1;

FIG. 11 is a timing diagram for explaining an incremental-step-pulse program (ISPP) scheme performed in the non-volatile memory device illustrated in FIG. 1;

FIG. 12 shows a relation between status register data and program/erase cycles;

FIG. 13 is a flowchart for explaining a wear leveling method performed in the memory system illustrated in FIG. 1;

FIG. 14 is a table for explaining a wear leveling managing method of the memory system illustrated in FIG. 1;

FIG. 15 shows a block diagram of a memory system including a non-volatile memory device according to another example embodiment;

FIG. 16 is a flowchart for explaining an operation of the memory system illustrated in FIG. 15;

FIG. 17 shows an example embodiment of a data processing system including the memory controller and the non-volatile memory device illustrated in FIG. 1 or FIG. 15; and

FIG. 18 shows another example embodiment of a data processing system including the memory controller and the non-volatile memory device illustrated in FIG. 1 or FIG. 15.

### DETAILED DESCRIPTION OF EXAMPLE EMBODIMENTS

Example embodiments now will be described more fully hereinafter with reference to the accompanying drawings, in which embodiments are shown. The example embodiment may, however, be embodied in many different forms and should not be construed as limited to those set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

“Method of operating nonvolatile memory device and memory system” under U.S. patent application Ser. No. 12/558,630 filed on Sep. 14, 2009 and “Nonvolatile memory device and related programming method” under U.S. patent application Ser. No. 12/726,408 filed on Mar.18, 2010 are incorporated by reference in their entirety.

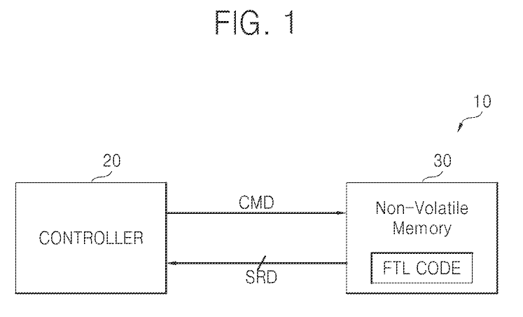

FIG. 1 shows a block diagram of a memory system including a non-volatile memory device according to an example embodiment. Referring to FIG. 1, the memory system 10 includes a memory controller 20 and a non-volatile memory device 30. The memory system 10 may be any system including a flash memory.

The memory controller 20 generates an address and a command, e.g., a program command, a read command or an erase command for controlling an operation, e.g., a program operation, a read operation or an erase operation, of the non-volatile memory device 30.

The program operation and the read operation are performed by page, and the erase operation is performed by block.

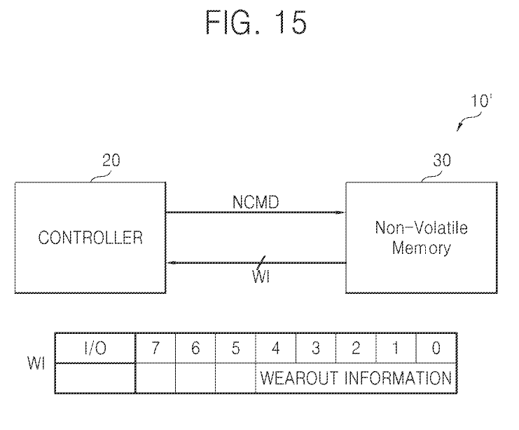

The memory controller 20 outputs a command CMD for detecting the deterioration degree of memory cells included in the non-volatile memory device 30 in real time. For example, the command CMD may be a command, e.g., a read status command, for acquiring information on success (or pass) or failure of an erase operation or a program operation from the non-volatile memory device 30. In addition, the command CMD may be a command explained referring to FIG. 15.

The non-volatile memory device 30 transmits deterioration degree information indicating the deterioration degree to the memory controller 20 according to the command CMD.

The deterioration degree information may be called a parameter value related to an erase operation or a program operation, information corresponding to the parameter value, or status register data SRD.

For example, the deterioration degree information includes any information required for determining the deterioration degree of each of a plurality of memory cells included in a page, which is an object of a program operation; or a block, which is an object of an erase operation.

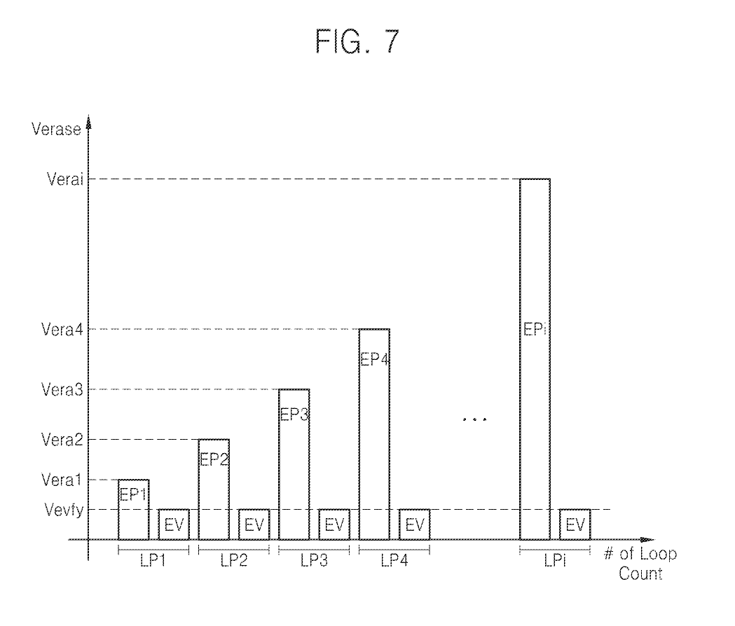

For example, the deterioration degree information related to an erase operation may include time needed until a block which is an object of the erase operation, is actually erased; an incremental-step-pulse erase (ISPE) loop count; an ISPE voltage, e.g., an ISPE final erase voltage; at least one of width and amplitude of each erase pulse EPi of each erase loop LP1 to LPi of FIG. 7; at least one of width and amplitude of an erase verify pulse EV of FIG. 7; temperature of the non-volatile memory device 30; temperature of the block; at least a voltage supplied to the block during the erase operation; an operational voltage(s) of the non-volatile memory device 30; and/or an erase count on the block.

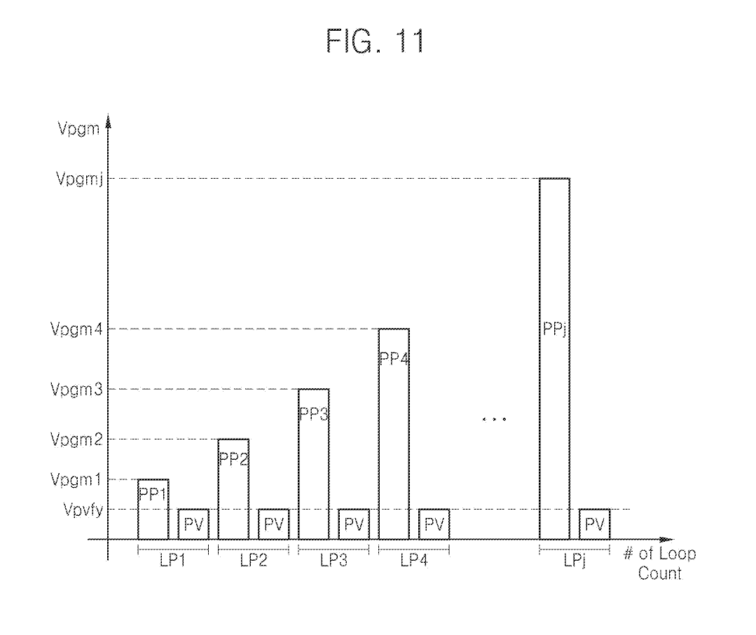

Moreover, the deterioration degree information related to a program operation includes time needed until a page, which is an object of the program operation, is actually programmed; an incremental-step-pulse program (ISPP) loop count; an ISPP voltage, e.g., an ISPP initial program voltage or an ISPP final program voltage; at least one of width and amplitude of each program pulse PPj of each program loop LP1 to LPj of FIG. 11; at least one of width and amplitude of a program verify pulse PV of FIG. 11; temperature of the non-volatile memory device 30; temperature of the page; at least a voltage supplied during the program operation; an operational voltage(s) of a non-volatile memory device 30; and/or a program count on the page.

The number of program/erase (P/E) cycles or Program/Erase (P/E) cycles affects deterioration of a flash memory cell. Here, a diagonal line “/” means and/or.

The memory controller 20 may perform wear-leveling by group according to the deterioration degree information output from the non-volatile memory device 30.

The ISPP scheme means a method supplying a program voltage, which increases by a voltage (e.g., constant voltage) per program loop, to a selected word line to control a cell distribution after programming within a desired width.

Additionally, the ISPE scheme means a method supplying an erase voltage, which increases by a voltage (e.g., a constant voltage) per erase loop, to a selected block to control a cell distribution within a desired width as an erase version of the ISPP scheme.

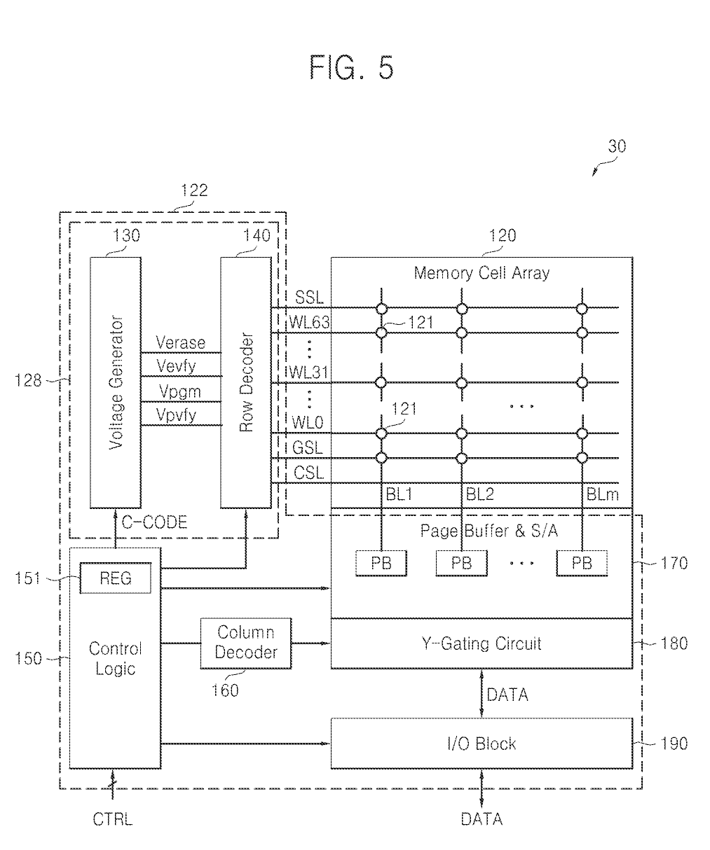

When the non-volatile memory device 30 performs an erase operation, a parameter value related to the erase operation or information corresponding to the parameter value, (e.g., one of an ISPE loop count, an ISPE voltage and a P/E cycle, is stored in a memory (e.g., a status register 151 or a memory cell array 120 embodied in the non-volatile memory device 30 illustrated in FIG. 5).

Moreover, when the non-volatile memory device 30 performs a program operation, a parameter value related to the program operation or information corresponding to the parameter value (e.g., one of an ISPP loop count, an ISPP voltage and a P/E cycle) is stored in a memory (e.g., a status register 151 or a memory cell array 120 embodied in the non-volatile memory device 30 illustrated in FIG. 5).

The non-volatile memory device 30 transmits state data information SRD stored in the memory to a memory controller 20 in response to the command CMD output from the memory controller 20.

Accordingly, the memory controller 20 may analyze (or decode) the status data information SRD, analyze deterioration degree of a currently programmed page or a currently erased block according to an analysis result, and perform wear-leveling on the page or the block according to an analysis result.

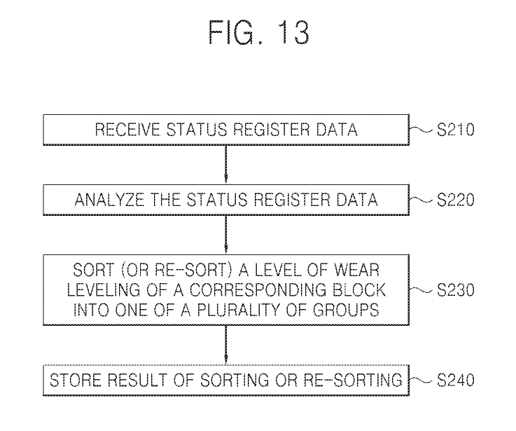

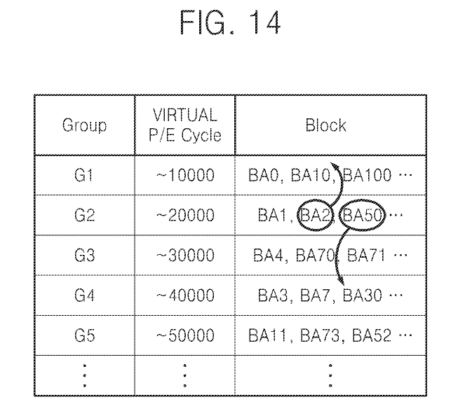

Wear-leveling performed on a group basis by the memory controller 20 will be explained in detail referring to FIGS. 13 and 14.

The memory controller 20 and the non-volatile memory device 30 may be packaged in a package, respectively. According to embodiments, the memory controller 20 and the non-volatile memory device 30 may be packaged in a multi-chip package (MCP).

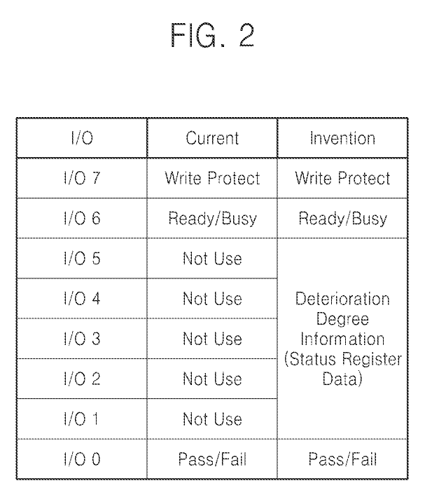

FIG. 2 shows an example embodiment of status register data output from the non-volatile memory device illustrated in FIG. 1.

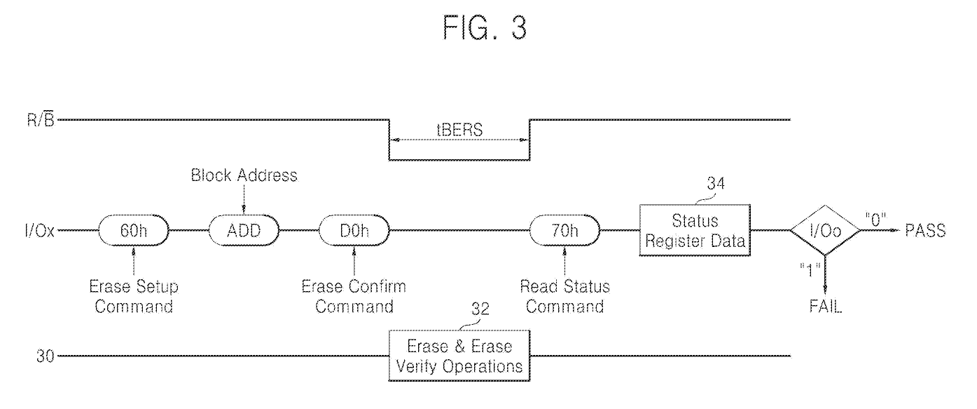

The memory controller 20 monitors an output of a status bit I/O 6 of a status register or ^{R/ B̅} illustrated in FIG. 3, detects termination (or completion) of a program operation (or a program cycle) or an erase operation (or an erase cycle) according to a monitoring result. When the program operation or the erase operation is terminated (or completed), the memory controller 20 transmits a command CMD, e.g., a read status command, to the non-volatile memory device 30.

The non-volatile memory device 30 transmits status register data SRD with a status bit or a write status bit I/O 0 to the memory controller 20.

As illustrated in FIG. 2, the non-volatile memory device 30 transmits deterioration degree information, i.e., status register data SRD, on a currently programmed page or a currently erased block to the memory controller 20 through data input/output pins I/O 1-I/O 5.

As described above, status register data SRD means deterioration degree information, a parameter value related to an erase operation or information corresponding to the parameter, a parameter value related to a program operation or information corresponding to the parameter, and/or data including the deterioration degree information and other information together.

The memory controller 20 may determine deterioration degree on a currently programmed page or a currently erased block by real time according to status register data SRD. The memory controller 20 may also determine success or failure of a program operation or an erase operation according to a level of write status bit I/O 0.

Table 1 is an exemplary table for explaining status register data SRD output for each possible ISPE loop count for a block.

TABLE 1

| I/O 5 | I/O 4 | I/O 3 | I/O 2 | I/O 1 | ISPE Loop Count |
|---|---|---|---|---|---|
| 0 | 0 | 0 | 0 | 1 | 1 |
| 0 | 0 | 0 | 1 | 0 | 2 |
| 0 | 0 | 0 | 1 | 1 | 3 |
| 0 | 0 | 1 | 1 | 1 | 4 |
| . . . | . . . | . . . | . . . | . . . | . . . |

Table 2 is an exemplary table for explaining status register data SRD output for the ISPE voltage (Verai of FIG. 7, i is a natural number, e.g., an ISPE final erase voltage) supplied to erase a block.

TABLE 2

| I/O 5 | I/O 4 | I/O 3 | I/O 2 | I/O 1 | ISPE Loop Voltage |
|---|---|---|---|---|---|
| 0 | 0 | 0 | 0 | 1 | Vera1 |
| 0 | 0 | 0 | 1 | 0 | Vera2 (Vera2 > Vera1) |
| 0 | 0 | 0 | 1 | 1 | Vera3 (Vera3 > Vera2) |
| 0 | 0 | 1 | 1 | 1 | Vera4 (Vera4 > Vera3) |
| . . . | . . . | . . . | . . . | . . . | . . . |

As illustrated in tables 1 and 2, as a memory cell, e.g., a single level cell (SLC) or a multi-level cell (MLC), included in a memory cell array of the non-volatile memory device 30 performing an erase operation by using an ISPE scheme becomes worn-out, an ISPE loop count or an ISPE loop voltage, e.g., an ISPE final erase voltage, increases.

Table 3 is an exemplary table for explaining status register data SRD output for each possible ISPP loop count for a by page.

TABLE 3

| I/O 5 | I/O 4 | I/O 3 | I/O 2 | I/O 1 | ISPP Loop Count |
|---|---|---|---|---|---|
| 0 | 0 | 0 | 0 | 1 | 1 |
| 0 | 0 | 0 | 1 | 0 | 2 |
| 0 | 0 | 0 | 1 | 1 | 3 |
| 0 | 0 | 1 | 1 | 1 | 4 |
| . . . | . . . | . . . | . . . | . . . | . . . |

Table 4 is an exemplary table for explaining status register data SRD output for the ISPP loop voltage supplied to program a page at every loop (Vpgmj, j is a natural number, e.g., an ISPP initial program voltage or an ISPP final program voltage).

TABLE 4

| I/O 5 | I/O 4 | I/O 3 | I/O 2 | I/O 1 | ISPP Loop Voltage |
|---|---|---|---|---|---|
| 0 | 0 | 0 | 0 | 1 | Vpgm1 |
| 0 | 0 | 0 | 1 | 0 | Vpgm2 (Vpgm2 > Vpgm1) |
| 0 | 0 | 0 | 1 | 1 | Vpgm3 (Vpgm3 > Vpgm2) |
| 0 | 0 | 1 | 1 | 1 | Vpgm4 (Vpgm4 > Vpgm3) |
| . . . | . . . | . . . | . . . | . . . | . . . |

As illustrated in tables 3 and 4, as a memory cell, e.g., a SLC or an MLC, included in a memory cell array of the non-volatile memory device 30 performing a program operation by using an ISPP scheme becomes worn-out, an ISPP loop count or an ISPP loop voltage, e.g., an ISPP initial program voltage or final program voltage, increases.

The memory controller 20 may analyze deterioration degree on a currently erased block or a currently programmed page by using status register data SRD, and the memory controller 20 may sort (or classify) a level of wear-leveling on the block or the page into a group according to an analysis result.

FIG. 3 shows an example embodiment of an operational timing diagram of the memory system illustrated in FIG. 1.

The ^{R/ B̅} output e.g., output of the I/O 6 indicates an operational status of the non-volatile memory device 30. When the ^{R/ B̅} output is in a low level, it means a program operation, a read operation, or an erase operation is performed in the non-volatile memory device 30. When the ^{R/ B̅} output is transited (or changed) from a low level to a high level, it means the program operation, the read operation, or the erase operation is completed.

Referring to FIGS. 1 to 3, to erase one of a plurality of blocks included in the non-volatile memory device 30, the memory controller 20 transmits a first command, e.g., an erase setup command which may be indicated in 60h, to the non-volatile memory device 30 through data pins I/Ox, where x is a natural number.

The memory controller 20 outputs a block address ADD for designating the one block and transmits a second command, e.g., an erase confirm command which may be indicated in D0h, to the non-volatile memory device 30 through data pins I/Ox.

According to the erase confirm command, the non-volatile memory device 30 performs an erase operation erasing a block designated by the block address ADD. Here, an ISPE scheme is applied. During a block erase time tBERS, the non-volatile memory device 30 changes a parameter value related to the erase operation, e.g., an ISPE loop count or an ISPE voltage, until the erase operation on the block is completed as illustrated in FIG. 7.

Information corresponding to a finally changed parameter value, e.g., a parameter value when an erase operation succeeds, may be stored in a memory, e.g., a status register 151 or a memory cell array 120 illustrated in FIG. 5. During the block erase time tBERS, an erase operation and an erase verify operation are performed 32.

When the erase operation is completed, ^{R/ B̅} output transits from a low level to a high level. The memory controller 20 transmits a third command, e.g., a read status command which may be indicated in 70h, to the non-volatile memory device 30 through data pins I/Ox in response to the ^{R/ B̅} D output which is transited to the high level.

The non-volatile memory device 30 transmits status register data SRD with a write status bit to the memory controller 20 according to the third command 34.

The memory controller 20 determines if an erase operation is successful or not according to the write status bit input through an input/output line I/O 0. When the write status bit is 0, the memory controller 20 determines the erase operation is successful PASS, and when the write status bit is 1, the memory controller 20 determines the erase operation failure FAIL.

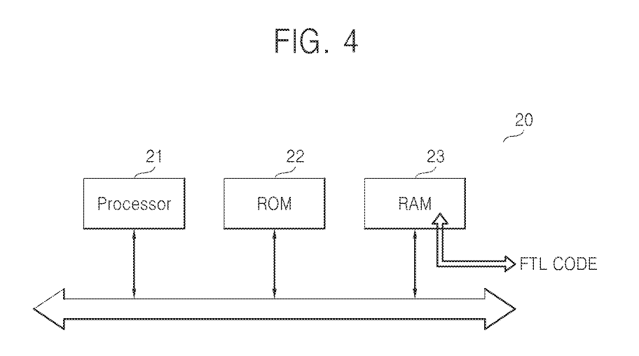

FIG. 4 shows a schematic block diagram of the memory controller illustrated in FIG. 1.

Referring to FIG. 4, the memory controller 20 includes a processor 21, a non-volatile memory device, e.g., read only memory (ROM) 22, and a volatile memory device e.g., a random access memory (RAM) or a static RAM (SRAM) 23.

In the non-volatile memory device 22, a program for performing a series of operations is stored as firmware.

The processor 21 performs the series of operations by performing the program stored in the non-volatile memory device 22.

Referring to FIGS. 1 to 4, the series of operations performed by the processor 21 are explained in detail.

The processor 21 transmits a block address ADD of the block and an erase command, e.g., D0h, to the non-volatile memory device 30 to erase a specific block in the non-volatile memory device 30.

The processor 21 transmits a read status command, e.g., 70h, to the non-volatile memory device 30 in response to the R/B output transited to a high level. The non-volatile memory device 30 outputs information corresponding to a finally changed parameter value, i.e., status register data SRD, which is stored in the memory, e.g., the status register 151 or the memory cell array 120 illustrated in FIG. 5, to the processor 21 according to the read status command.

The processor 21 analyzes (or decodes) received status register data SRD, classifies (or sorts) a level of wear leveling of the block (where a current erase operation is performed) into one of a plurality of groups according to an analysis result, and transmits a classification (or sorting) result to the non-volatile memory device 30.

The processor 21 loads a flash translation layer code (FTL code) stored in the non-volatile memory device 30 on the RAM 23 to perform wear-leveling by group.

FIG. 5 shows a block diagram of the non-volatile memory device illustrated in FIG. 1.

Referring to FIG. 5, the non-volatile memory device 30 includes a memory cell array 120 for storing data and an access circuit 122.

As described above, a program operation and a read operation are performed by page, and an erase operation is performed by block (or memory block). Accordingly, a block is a group of a plurality of pages.

The memory cell array 120 includes each NAND memory cell string connected to each bit line BL1 to BLm, where m is a natural number, and the each NAND memory cell string includes a plurality of non-volatile memory cells 121 connected in series. According to an example embodiment, the memory cell array 120 may be three-dimensionally embodied through a wafer stack, a chip stack or a cell stack.

Each NAND memory cell string may be arranged or embodied on a two-dimension plane or layer.

The NAND memory cell string includes the plurality of non-volatile memory cells 121 connected in series between a string selection transistor (not shown) connected to a bit line BL1 and a ground selection transistor (not shown) connected to a common source line CSL.

A gate of the string selection transistor is connected to a string selection line SSL, each gate of the plurality of non-volatile memory cells 121 is connected to each of a plurality of word lines WL0 to WL63, and a gate of the ground selection transistor is connected to a ground selection line GSL.

For convenience of explanation, FIG. 5 illustrates 64 word lines WL0 to WL63, however, the number of word lines is not restricted thereto in the present invention.

Each of the plurality of non-volatile memory cells 121 included in each NAND memory cell string may be embodied in a flash Electrically Erasable Programmable Read-Only Memory (EEPROM) storing a bit or more.

Accordingly, each of the plurality of non-volatile memory cells 121 may be embodied in a NAND flash memory cell, e.g., a single level cell (SLC) or a multi-level cell (MLC), which may store a bit or more.

The access circuit 122 accesses the memory cell array 120 to perform a data access operation, e.g., a program operation, a read operation or an erase operation, according to a command (or command sets) and an address output from outside, e.g., the memory controller 20.

The access circuit 122 includes a voltage supply circuit 128, a control logic 150, a column decoder 160, a page buffer & sense amplifier block 170, a Y-gating circuit 180 and an input/output block 190.

According to a control code C-CODE generated by the control logic 150, the voltage supply circuit 128 may generate at least one voltage necessary for a data access operation according to an ISPE scheme or an ISPP scheme.

For example, during a program operation, a program voltage Vpgm is supplied to a selected word line among the plurality of word lines WL0 to WL63, a pass voltage is supplied to the un-selected word lines among the plurality of word lines WL0 to WL63, a ground voltage is supplied to a GSL, a CSL and a bulk, and a supply voltage is supplied to a SSL.

For example, during an erase operation, an erase voltage Verase is supplied to a bulk of each NAND memory cell included in each NAND memory cell string and a ground voltage is supplied to the plurality of word lines WL0 to WL63.

The voltage supply circuit 128 includes a voltage generator 130 and a row decoder 140.

According to a control code C_CODE, the voltage generator 130 generates a program voltage Vpgm and a program verify voltage Vpvfy for performing the program operation, generates read voltages for performing the read operation, generates an erase voltage Verase and an erase verify voltage Vevfy for performing the erase operation, and outputs at least one voltage for each operation to a row decoder 140.

The control logic 150 controls a whole operation of the access circuit 122 according to a control signal CTRL output from the memory controller 20. For example, the control logic 150 may store changed deterioration degree information in the status register 151 or the memory cell array 120 until deterioration degree information generated during a program operation or an erase operation is completed.

According to a command output from the memory controller 20, the control logic 150 may output deterioration degree information stored in the status register 151 or the memory cell array 120 to the memory controller 20 as status register data.

The column decoder 160 decodes column addresses under a control of the control logic 150 and outputs a plurality of selection signals to the Y-gating circuit 180.

The page buffer & sense amplifier block 170 includes a plurality of page buffers PB. Each of the plurality of page buffers PB is connected to each of a plurality of bit lines BL1 to BLm.

Each of the plurality of page buffers PB may operate as a driver for programming data in the memory cell array 120 during a program operation according to a control of the control logic 150. In addition, each of the plurality of page buffers PB may operate as a sense amplifier, which may sense amplify each voltage level of the plurality of bit lines BL1 to BLm during a read operation or a verify operation according to a control of the control logic 150.

The Y-gating circuit 180 may control transmission of data between the page buffer & sense amplifier block 170 and the input/output block 190 in response to a plurality of selection signals output from the column decoder 160.

The input/output block 190 may transmit data input from outside to the Y-gating circuit 180 or transmit data output from the Y-gating circuit 180 to the memory controller 20 through a plurality of input/output pins or data buses.

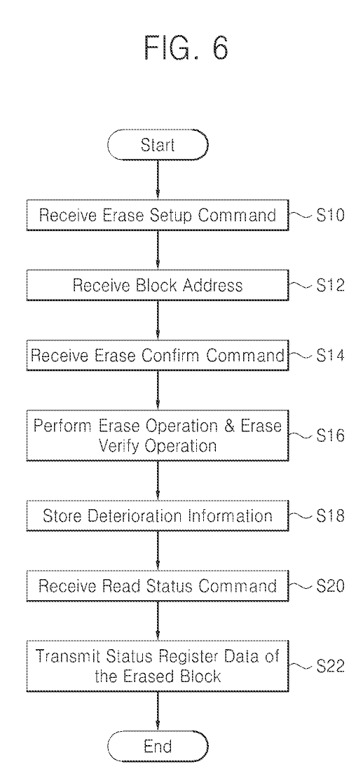

FIG. 6 is a flowchart for explaining an erase operation of the non-volatile memory device illustrated in FIG. 1 and an output process of status register data. Referring to FIGS. 1 to 6, an erase operation of the non-volatile memory device 30 is explained as follows.

The non-volatile memory device 30 receives an erase setup command, e.g., 60h, output from the memory controller 20 (S10).

The non-volatile memory device 30 receives a block address ADD and an erase confirm command, e.g., D0h, output from the memory controller 20 successively (S12 and S14).

According to a control of the control logic 150, the access circuit 122 of the non-volatile memory device 30 performs an erase operation and an erase verify operation on a block selected by a block address ADD. The block is embodied in the memory cell array 120.

Until an erase operation performed on the block designated by the block address ADD according to the erase command is completed, the control logic 150 changes a parameter value related to the erase operation and stores a finally changed parameter value, e.g., a parameter value used when the erase operation is completed, in the status register 151 or the memory cell array 120 (S18).

The control logic 150 receives a command, e.g., a read status command, output from the memory controller 20 (S20), and transmits deterioration degree information, i.e., status register data SRD, corresponding to a parameter value stored in the status register 151 or the memory cell array 120 to the memory controller 20 according to the received command (S22).

The deterioration degree information is information for a parameter value, i.e., an ISPE loop count or an ISPE voltage.

According to an example embodiment, the deterioration degree information is transmitted with a write status bit I/O 0 indicating success or failure of the erase operation to the controller 20.

FIG. 7 is a timing diagram for explaining an ISPE scheme performed in the non-volatile memory device illustrated in FIG. 1.

EPi, where i is a natural number, means an erase pulse according to an ISPE scheme, Verai, where i is a natural number, means an erase voltage, EV means an erase verify pulse used in an erase verify operation, and Vevfy means an erase verify voltage.

As illustrated in FIG. 7, an ISPE maximum loop count is assumed to be i times, and each erase loop LP1 to LPi includes each erase pulse EPi and an erase verify pulse EV.

The voltage generator 130 performs the erase operation according to the control code C-CODE by increasing successively an ISPE erase voltage Verai, where i is a natural number, until the erase operation is completed or until the erase operation succeeds.

For example, the erase operation may be completed at a first ISPE loop LP1 where a first erase voltage Vrea1 is supplied. In this case, the first erase voltage Vrea1 may be an ISPE final erase voltage. Accordingly, the control logic 150 may store deterioration degree information indicating the first erase voltage Vrea1 or an ISPE loop count, e.g., 1, in the status register 151 as status register data or the memory cell array 120.

In addition, the erase operation may be completed at a third ISPE loop LP3 where a third erase voltage Vera3 is supplied. In this case, the third erase voltage Vrea3 may be an ISPE final erase voltage. Accordingly, the control logic 150 may store deterioration degree information, i.e., a finally changed parameter value, indicating the third erase voltage Vrea3 or an ISPE loop count, e.g., 3, in the status register 151 as status register data or the memory cell array 120.

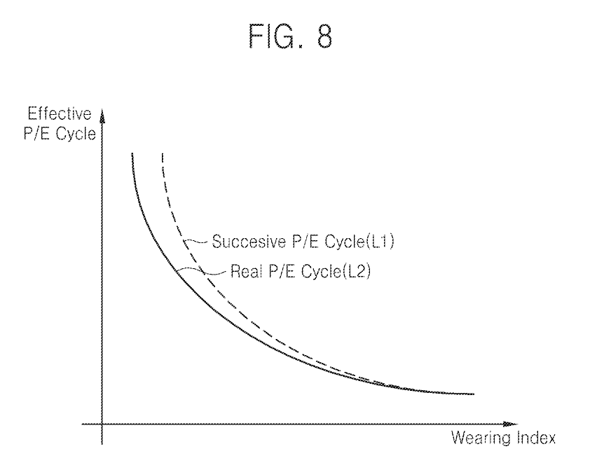

FIG. 8 shows a wearing index and the program/erase cycles.

Referring to FIG. 8, L1 is a curve showing a wearing index and an effective program and/or erase (P/E) cycle when P/E is successively performed on a specific block, e.g., a test step, and L2 is a curve showing a wearing index and an effective program and/or erase cycle when P/E is discontinuously performed on a specific block, e.g., an actual use step. As time goes by, the L1 is changed to the L2. That is, as time goes by, a deteriorated non-volatile memory cell included in the specific block is naturally recovered. Accordingly, some of the present inventive concepts are about detecting deterioration degree on the specific block where L2 is reflected.

As described above, the memory controller 20 may detect deterioration degree on the specific block at a time point when a current erase operation is performed by real time by using deterioration information, a parameter value related to an erase operation, a parameter value for a program operation, i.e., status register data SRD, and sort the block into a specific group according to a detection result.

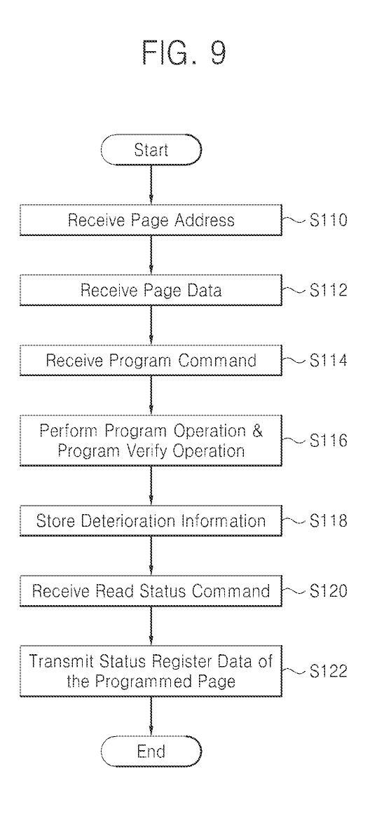

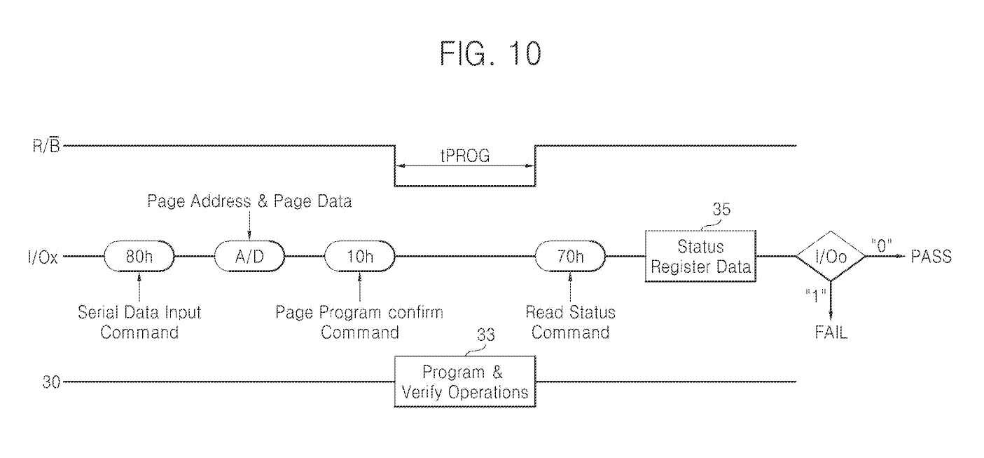

FIG. 9 is a flowchart for explaining a program operation of the non-volatile memory device illustrated in FIG. 1 and an output process of status register data, and FIG. 10 shows another example embodiment of an operational timing diagram of the memory system illustrated in FIG. 1.

Referring to FIGS. 1, 2, 4, 5, 9 and 10, the control logic 150 of the non-volatile memory device 30 receives a serial data input command, e.g., 80h, output from the processor 21.

The control logic 150 of the non-volatile memory device 30 receives a page address and page data A/D successively (S110 and S112).

The control logic 150 of the non-volatile memory device 30 receives a program command, e.g., a page program confirm command indicated in 10h (S114).

Until a program operation programming the page data in a page of the memory cell array 120, which is corresponding to the page address, according to the program command is completed, the control logic 150 of the non-volatile memory device 30 changes a parameter value related to the program operation.

During a program time tPROG, the access circuit 122 of the non-volatile memory device 30 performs a program operation and a program verify operation (S116 of FIGS. 9 and 33 of FIG. 10).

When the program operation is completed, the control logic 150 stores a finally changed parameter value in the status register 151 or the memory cell array 120 as status register data (S118).

The processor 21 transmits a read status command, e.g., 70h, to the non-volatile memory device 30 according to a ^{R/ B̅} output transited to a high level. The non-volatile memory device 30 receives the read status command (S120), and outputs information, i.e., status register data SRD, corresponding to a finally changed parameter value stored in the memory, e.g., the status register 151 or the memory cell array 120 illustrated in FIG. 5, to the processor 21 according to the received read status command (S122 of FIGS. 9 and 35 of FIG. 10).

The processor 21 interprets (or analyzes) a received status register data SRD, sorts a level of wear-leveling on the block into one of a plurality of groups according to an interpretation (or analysis) result, and transmits a sorting result to the non-volatile memory device 30 to store it as a flash translation layer (FTL) code.

The parameter value may be an ISPP loop count or an ISPP voltage. Deterioration degree information i.e., status register data SRD may be transmitted with a write status bit indicating success or failure of the program operation to the memory controller 20.

FIG. 11 is a timing diagram for explaining an ISPP scheme performed in the non-volatile memory device illustrated in FIG. 1.

PPj, where j is a natural number, means a program pulse, Vpgmj, where j is a natural number, means a program voltage, PV means a program verify pulse used in a program verify operation, and Vpvfy means a program verify voltage. During the program verify operation, an identical voltage may be supplied to a selected word line more than twice at a different time, and each different voltage may be supplied to the selected word line more than twice at a different time.

As illustrated in FIG. 11, an ISPP maximum loop count is assumed to be j times and each program loop LP1 to LPj includes each program pulse PP and a program verify pulse PV.

According to a control code C-CODE, until a program operation is completed, the voltage generator 130 performs the program operation by increasing an ISPP program voltage Vpgmj, where j is a natural number, successively.

For example, the program operation may be completed at a first ISPP loop LP1 where a first program voltage Vpgml is supplied. In this case, the first program voltage Vpgml may be an ISPP final program voltage. Accordingly, the control logic 150 may store information, i.e., a finally changed parameter value, indicating the first program voltage Vpgm1 or an ISPP loop count, e.g., 1, in the status register 151 or the memory cell array 120 as status register data.

Moreover, the program operation may be completed at a fourth ISPP loop LP4 where a fourth program voltage Vpgm4 is supplied. In this case, the fourth program voltage Vpgm4 may be an ISPP final program voltage. Accordingly, the control logic 150 may store information indicating the fourth program voltage Vpgm4 or an ISPP loop count, e.g., 4, in the status register 151 or the memory cell array 120.

According to an example embodiment, an ISPP initial program voltage may be stored in the status register 151 as deterioration degree information.

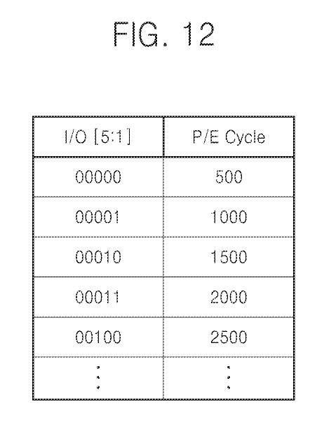

FIG. 12 shows a relation between status register data and program/erase cycles. Referring to FIG. 12, a relation between status register data (SRD=I/0[5:1]) and P/E cycles is illustrated.

As illustrated in FIG. 12, when the P/E cycles are not more than 500 times, the status register data (SRD=I/0[5:1]) may be 00000. When the P/E cycles are more than 500 times and not more than 1000 times, the status register data (SRD=I/0[5:1]) may be 00001, and when the P/E cycles are more than 1000 times and not more than 1500 times, the status register data (SRD=I/0[5:1]) may be 00010.

Referring to FIGS. 1 and 12, the control logic 150 may store information indicating the number of performed program operations or erase operations, i.e., a P/E cycle, in the status register 151 or the memory cell array 120.

Accordingly, the control logic 150 may output information showing a P/E cycle stored in the status register 151 or the memory cell array 120 to the memory controller 20 as status register data SRD according to a read status command output from the memory controller 20 after the program operation or the erase operation is performed.

According to an example embodiment, deterioration degree information may be output to the memory controller 20 as status register data SRD automatically after a program operation or an erase operation is completed.

FIG. 13 is a flowchart for explaining a wear leveling method performed in the memory system illustrated in FIG. 1, and FIG. 14 is a table for explaining a wear leveling managing method of the memory system illustrated in FIG. 1.

Referring to FIGS. 1, 2, 4, 13 and 14, the processor 21 receives status register data SRD, i.e., deterioration degree information, output from the non-volatile memory device 30 (S210).

The processor 21 interprets (or decodes) received status register data SRD (S220), and sorts a level of wear leveling of a currently erased block, e.g., BA2, into a group, e.g., G2, among a plurality of groups G1, G2, G3, G4, G5, . . . according to an interpretation result (S230). Such sorting is not simply based on erase count, but based on deterioration degree or deterioration degree information of a non-volatile memory cell included in the block.

For example, the processor 21 may determine deterioration indicators from the deterioration information parameters, and sort the erased block based on the determined deterioration indicators. As an example, the processor 21 may determine an erase loop count as a deterioration indicator. The erase loop count may be determined as equal to (final erase voltage-start erase voltage)/erase voltage interval, where the erase voltage interval is one of the voltage intervals Vera(i+1)-Verai shown in FIG. 7. As another example, the processor 21 may determine an erase loop count as equal to (total erase time/erase time for one loop). The same deterioration indicators may be determined based on the deterioration parameters for program operations. Accordingly, the determined erase loop count and the determined program loop count may be combined by the processor 21 to determine a virtual P/E cycle. The processor 21 may then sort the block based the determined virtual P/E cycle.

As illustrated in FIG. 14, blocks which are sorted into a first group G1 and have a virtual P/E cycle not more than 10,000 times is BA0, BA10, BA100 and so on, blocks which are sorted into a second group G2 and have a virtual P/E cycle more than 10,000 times and not more than 20,000 times are BA1, BA2, BA50 and so on, and blocks which are sorted into a third group G3 and have a virtual P/E cycle more than 20,000 times and not more than 30,000 times are BA4, BA70, BA71 and so on.

The processor 21 may store a sorting result in the memory cell array 120 of the non-volatile memory device 30 as a FTL code. For example, the sorting result may be recorded in a FTL code and stored in the memory cell array 120. The FTL code may be used as an indicator (or index) performing wear-leveling by group.

When a level of current wear-leveling belonging to a block, e.g., BA2, which belongs to a group, e.g., G2, among the plurality of wear-leveling groups G1, G2, G3, G4, G5, . . . , the processor 21 may re-sort the block, e.g., BA2 and BA50, into another group, e.g., G1 and G4, according to an interpretation (or analysis) result of received status register data SRD and store a re-sorting result in the memory cell array 120 of the non-volatile memory device 30. Namely, unlike simply counting P/E cycles, the wear-leveling group into which blocks are sorted may change. Subsequently, according to wear-leveling performed by group according to deterioration degree of a relevant block, a life time of the non-volatile memory device 30 may get longer.

The processor 21 uses deterioration degree information as an indicator which may indicate by real time an amount of charge trapped in each of a plurality of non-volatile memory cells, which are included in a currently erased block. Accordingly, the processor 21 determines wear-out of the relevant block based on an amount of charge trapped in each of the plurality of non-volatile memory cells instead of deciding wear-out of a relevant block uniformly by counting the number of P/E simply.

For example, since the non-volatile memory device 30 stores a finally changed parameter value (or every changed parameter value) or a finally updated parameter value (or every updated parameter value) during an erase operation or a program operation and does not store additional erase count, it may reduce a memory region storing metadata, e.g., an erase count.

When it is assumed that two bytes are needed to store an erase count at every block, it is possible to decrease a memory region of 4Kbyte in case of the non-volatile memory device 30 includes 2,048 blocks.

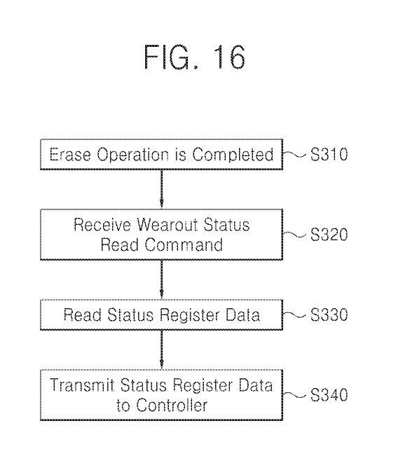

FIG. 15 shows a block diagram of a memory system including a non-volatile memory device according to another example embodiment, and FIG. 16 is a flowchart for explaining an operation of a memory system illustrated in FIG. 15.

Referring to FIGS. 5, 15 and 16, the memory controller 20 of the memory system 10′ outputs a dedicated command NCMD for getting deterioration degree information, e.g., a wear out status read command, to the non-volatile memory device 30.

The non-volatile memory device 30 stores deterioration degree information on the block used when an erase operation on a current erase block is completed, e.g., a parameter value related to the erase operation or information corresponding to the parameter, in the status register 151.

When the erase operation is completed (S310), the control logic 150 receives the wear out status read command (S320), reads deterioration degree information stored in the status register 151, e.g., status register data indicating wear-out information (S330), and transmits read status register data SRD to the memory controller 20 (S340).

The processor 21 interprets (or analyzes) received status register data SRD, and sorts a level of wear leveling of a currently erased block into one of a plurality of groups according to an interpretation (or analysis) result.

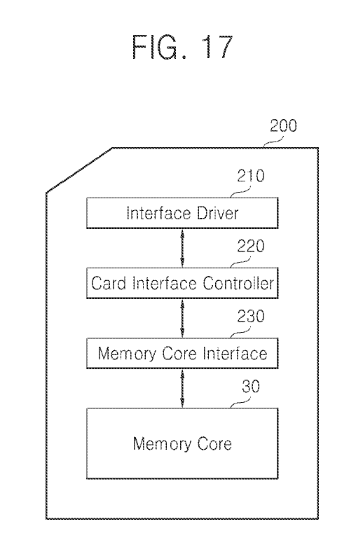

FIG. 17 shows an example embodiment of a data processing system including the memory controller and the non-volatile memory device illustrated in FIG. 1 or FIG. 15.

The data processing system 200 may be embodied in a smart card or a memory card. The data processing system 200 includes a memory core 30, an interface driver 210, a card interface controller 220, and a memory core interface 230.

The structure and an operation of the memory core 30 are equal or similar to the structure and an operation of the non-volatile memory device 30 illustrated in FIG. 5. The interface driver 210 drives signals output from a host and transmits driven signals to the card interface controller 220.

The structure and a function of the card interface controller 220 are substantially the same as the structure and a function of the memory controller 20 illustrated in FIG. 1 or FIG. 15. That is, the card interface controller 220 outputs a command for getting deterioration degree information on a block of the memory core 30 where a current erase operation is performed to the memory core 30, receives and analyzes status register data output from the memory core 30, and sorts a level of wear-leveling of the block into one of a plurality of groups according to an analysis result.

The memory core 30 and the card interface controller 220 communicate through the memory core interface 230.

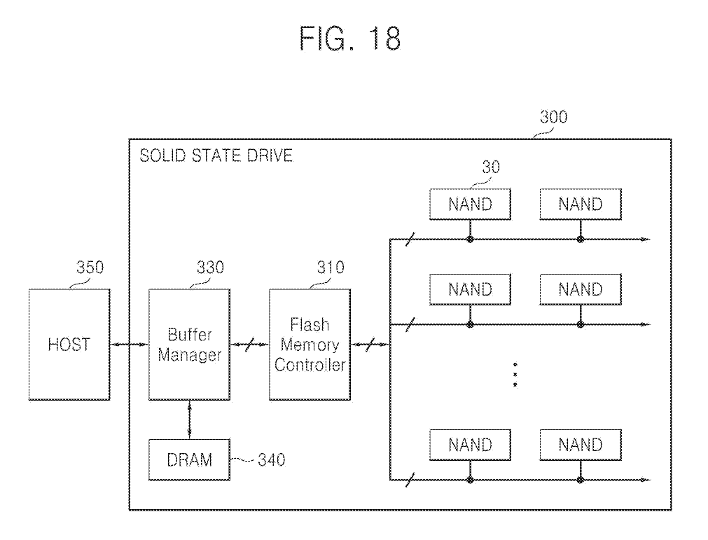

FIG. 18 shows another example embodiment of a data processing system including the memory controller and the non-volatile memory device illustrated in FIG. 1 or 15.

Referring to FIG. 18, a data processing system includes a data processing device 300 like solid state drive (SSD) and a host 350.

The data processing system 300 may include a plurality of flash memory devices 30, a flash memory controller 310 which may control each data processing operation of a plurality of flash memory devices 30, a volatile memory device 340 like a dynamic random access memory (DRAM), and a buffer manager 330 controlling storage of data which is exchanged between the flash memory controller 310 and the host 350 in the volatile memory device 340.

The memory system 10 or 10′ illustrated in FIG. 1 or FIG. 15 may be embodied in a personal computer (PC), a cellular phone, a smart phone, a tablet PC, a personal digital assistant (PDA), a portable multimedia player (PMP), a MP3 player, a digital camera, a navigation device, a console, an e-book, or a handheld electronic device and so on.

The method and/or the device according to an embodiment of the present invention may detect exactly deterioration degree of a flash memory cell by real time.

Accordingly, the method and/or the device of the present invention may perform wear-leveling adaptively according to the deterioration degree of the flash memory cell.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. An operation method of a non-volatile memory device comprising:
receiving a block address and an erase command output from a controller;
changing, until an erase operation performed according to the erase command is completed on a block corresponding to the block address, a parameter value related to the erase operation;
storing information corresponding to a finally changed parameter value; and
transmitting the information to the controller according to a command output from the controller.

2. The operation method of claim 1, wherein the command is a read status command requiring information on success or failure of the erase operation.

3. The operation method of claim 2, wherein the parameter value is at least one of time needed until the block is erased, an incremental-step-pulse erase (ISPE) loop count, an incremental-step-pulse erase (ISPE) voltage, at least one of width and amplitude of each erase pulse of each erase loop of the ISPE, at least one of width and amplitude of an erase verify pulse, temperature of the non-volatile memory device, a voltage supplied to the block during the erase operation, and an erase count on the block.

4. The operation method of claim 2, wherein the information is transmitted with a status bit indicating success or failure of the erase operation to the controller.

5. An operation method of a controller comprising:
transmitting, so as to erase a block in a non-volatile memory device, a block address on the block and an erase command to the non-volatile memory device;
transmitting a command to the non-volatile memory device;
receiving information which is output from the non-volatile memory device in response to the command and corresponds to a parameter value related to an erase operation according to the erase command;
analyzing the received information; and
sorting a level of wear-leveling of the block into one of a plurality of groups according to the analyzing.

6. The operation method of claim 5, wherein the command is a read status command requiring information on success or failure of the erase operation.

7. The operation method of claim 6, further comprising:
re-sorting a level of current wear-leveling of the block.

8. The operation method of claim 7, further comprising;
transmitting, by the controller, a result of the sorting or the re-sorting to the non-volatile memory device.

9. The operation method of claim 6, wherein the information indicates at least one of time needed until the block is erased, an incremental-step-pulse erase (ISPE) loop count, an incremental-step-pulse erase (ISPE) voltage, at least one of width and amplitude of each erase pulse of each erase loop of the ISPE, at least one of width and amplitude of an erase verify pulse, temperature of the non-volatile memory device, a voltage supplied to the block during the erase operation, and an erase count on the block.

10. An operational method of a memory system including a non-volatile memory device where a block is embodied and a controller controlling an operation of the non-volatile memory device comprising:
transmitting, by the controller, a block address on the block and an erase command to the non-volatile memory device;
transmitting, by the controller, a command to the non-volatile memory device;
receiving, by the controller, information, which is output from the non-volatile memory device in response to the command and corresponds to a parameter value related to an erase operation according to the erase command;
analyzing, by the controller, the information; and
sorting a level of wear-leveling of the block into one of a plurality of groups according to the analyzing.

11. The operation method of claim 10, further comprising:
changing, by the non-volatile memory device, the parameter value related to the erase operation until the erase operation on the block performed according to the erase command is completed;
storing a finally changed parameter value as the information; and
transmitting, by the non-volatile memory device, the information to the controller, when the command is a read status command, in response to the read status command.

12. The operation method of claim 11, further comprising:
re-sorting, by the controller, a level of wear-leveling of the block, the re-sorting resulting in at least one block changing from one group to another.

13. The operation method of claim 11, wherein the information indicates at least one of time needed until the block is erased, an incremental-step-pulse erase (ISPE) loop count, an incremental-step-pulse erase (ISPE) voltage, at least one of width and amplitude of each erase pulse of each erase loop of the ISPE, at least one of width and amplitude of an erase verify pulse, temperature of the non-volatile memory device, a voltage supplied to the block during the erase operation, and an erase count on the block.

14. The operation method of claim 10, wherein the memory system is a smart card.

15. The operation method of claim 10, wherein the memory system is a solid state drive (SSD).

16.-20. (canceled)

21. A method of wear-leveling, comprising:
receiving deterioration information for a block in a non-volatile memory;
determining at least one deterioration indicator based on the deterioration information, the deterioration indicator representing an amount of charge trapped in memory cells of the block; and
sorting the block into a wear-leveling group based on the deterioration indicator.

22. The operation method of claim 21, wherein deterioration information includes at least one of time needed until the block is erased, an incremental-step-pulse erase (ISPE) loop count, an incremental-step-pulse erase (ISPE) voltage, at least one of width and amplitude of each erase pulse of each erase loop of the ISPE, at least one of width and amplitude of an erase verify pulse, temperature of the non-volatile memory device, a voltage supplied to the block during the erase operation, and an erase count on the block.
